(19) United States
(12) Patent Application Publication
(10) Pub. No.: US 2019/0172861 A1
(43) Pub. Date: Jun. 6, 2019

(54) SEMICONDUCTOR PACKAGE AND RELATED METHODS

(71) Applicant: SEMICONDUCTOR COMPONENTS INDUSTRIES, LLC, Phoenix, AZ (US)

(72) Inventor: Yu-Te HSIEH, TAOYUAN CITY (TW)

(73) Assignee: SEMICONDUCTOR COMPONENTS INDUSTRIES, LLC, Phoenix, AZ (US)

(21) Appl. No.: 15/831,663

(22) Filed: Dec. 5, 2017

(51) Int. Cl. H01L 27/146; H01L 23/552; H01L 23/60; H01L 23/00

(52) U.S. Cl. CPC H01L 27/14618; H01L 23/552; H01L 27/14683; H01L 24/97; H01L 23/60

(57) ABSTRACT

Implementations of semiconductor packages may include: a substrate, a die electrically coupled to the substrate, and a wall coupled to the substrate wall. The wall may extend around a perimeter of the die. The wall may include a molding dam formed therein. The semiconductor package may also include a glass lid coupled to the wall and the molding dam. A mold compound may be coupled into the molding dam and across a thickness of the glass lid.

### BACKGROUND

### 1. Technical Field

Aspects of this document relate generally to semiconductor packages such as chip scale packages for image sensor arrays. More specific implementations involve complementary metal-oxide-semiconductor CMOS image sensors (CIS), plastic leadless chip carriers (PLCC), and ceramic leadless chip carriers (CLCC).

### 2. Background

Conventionally, to seal a semiconductor package a dry film or resin is applied to the glass lid. The glass lid is then attached to a substrate using the dry film or resin. This technique helps control glass tilt and helps with gap height consistency.

### SUMMARY

Implementations of semiconductor packages may include: a substrate, a die electrically coupled to the substrate, and a wall coupled to the substrate wall. The wall may extend around a perimeter of the die. The wall may include a molding dam formed therein. The semiconductor package may also include a glass lid coupled to the wall and the molding dam. A mold compound may be coupled into the molding dam and across a thickness of the glass lid.

Implementations of semiconductor packages may include one, all, or any of the following:

The substrate may be a printed circuit board, a ceramic material, or a lead frame.

The wall may be formed through transfer molding, compression molding, or injection molding.

The molding compound may be one of granular epoxy, resin, epoxy, silicone, acrylic, polyimide, or any combination thereof.

The molding compound may form a hermetic seal.

The semiconductor package may be a plastic leadless chip carrier (PLCC), a ceramic leadless chip carrier (CLCC), or a complementary metal-oxide-semiconductor (CMOS) image sensor (CIS).

Implementations of semiconductor packages may include: a substrate and one or more die electrically coupled to the substrate. The semiconductor package may also include a wall coupled to the substrate and a glass lid. The wall may extend around a perimeter of the die. A metal layer may be coupled across a thickness of the substrate, the wall, and a thickness of the glass lid. The metal layer may form a substantially hermetic seal for the one or more die.

Implementations of semiconductor packages may include one, all, or any of the following:

The substrate may be a printed circuit board, a ceramic material, or a lead frame.

The metal layer may include nickel, copper, aluminum, chromium, or any combination thereof.

The metal layer may be coupled to the semiconductor package through one of plasma sputtering, chemical vapor deposition, electrical plating, electroless plating, or immersion plating.

The metal layer may protect the semiconductor package from electromagnetic interference (EMI) and electrostatic discharge (ESD).

The semiconductor package may be a plastic leadless chip carrier (PLCC), a ceramic leadless chip carrier (CLCC), or a complementary metal-oxide-semiconductor (CMOS) image sensor (CIS).

Implementations of a method for forming semiconductor packages may include: providing a substrate sheet, coupling two or more walls to the substrate sheet. The two or more walls may be located around two or more die locations of the substrate sheet. The two or more walls may include a molding dam therein. The method may also include coupling two or more die to the substrate at the two or more die locations and coupling two or more glass lids to the two or more walls over the two or more die. The method may include applying mold compound into the molding dam of the two or more walls and singulating two or more semiconductor packages at the molding dam. The molding dam may securely couple the two or more glass lids to the two or more walls.

Implementations of methods for forming semiconductor packages may include one, all, or any of the following:

The molding compound may extend across a thickness of the glass.

The substrate sheet may include a printed circuit board, a ceramic material, or a lead frame.

The two or more walls may be formed through one of transfer molding, compression molding, or any combination thereof.

The mold compound may include resin, epoxy, silicon, acrylic, polyimide, or any combination thereof.

The molding compound may form a hermetic seal.

The mold compound may be applied through one of a dispenser or a coater.

The two or more semiconductor packages may include plastic leadless chip carriers (PLCC), ceramic leadless chip carriers (CLCC), and complementary metal-oxide-semiconductor (CMOS) image sensors (CIS).

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a cross section view of an implementation of a semiconductor package as described herein;

FIG. 2A is a side view of an implementation of a substrate sheet with two or more walls coupled thereto;

FIG. 2B is a side view of an implementation of a substrate sheet with two or more die coupled thereto;

FIG. 2C is a side view of an implementation of a substrate sheet with two or more glass lids coupled to two or more walls;

FIG. 2D is a side view of an implementation of a substrate sheet with molding compound in molding dams between two or more glass lids;

FIG. 2E is a side view of an implementation of a semiconductor package after singulation of a substrate sheet;

FIG. 3 is a side view of an implementation of a semiconductor package with a metal layer coupled across a thickness of the substrate, wall, and glass lid of a semiconductor package; and

FIG. 4A-4B is an implementation of a method for plating metal on the side walls of a semiconductor package.

### DESCRIPTION

This disclosure, its aspects and implementations, are not limited to the specific components, assembly procedures or method elements disclosed herein. Many additional components, assembly procedures and/or method elements known in the art consistent with the intended semiconductor packages will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such semiconductor packages, and implementing components and methods, consistent with the intended operation and methods.

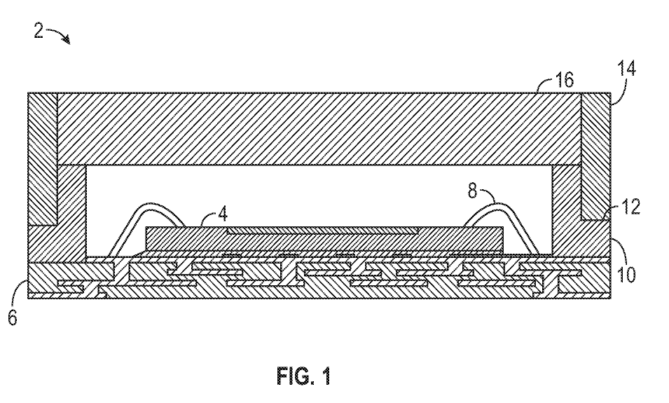

Referring to FIG. 1, a cross section of an implementation of a semiconductor package 2 is illustrated. The semiconductor package includes a die 4 coupled to a substrate 6 through two or more wire bonds 8. In various implementations, the die may be coupled to the substrate through other methods not including wire bonds, such as by non-limiting example, ball grid arrays (BGA), land grid arrays (LGA), solder balls, and other interconnect techniques. By non-limiting example, the die may be an image sensor chip. In various implementations, the substrate may be, by non-limiting example, a printed circuit board, a ceramic material, a lead frame, or other suitable material known in the art. The printed circuit board could be made of Bismaleimide-Triazine (BT) resin, FR-4 grade glass-reinforced epoxy laminate, FR-5 grade glass-reinforced epoxy laminate, and any combination thereof.

As illustrated in FIG. 1, a wall 10 is coupled to the substrate and extends around the perimeter of the die. The wall may be formed through, by non-limiting example, transfer molding, compression molding, injection molding, or other methods of forming materials on a substrate. The wall may be coupled to the substrate through the adhesion properties between the molding compound and the substrate. As illustrated, the wall 10 includes a molding dam 12 that is filled with a molding compound 14. The molding compound 14 couples a glass lid 16 to the upper surface of the wall 10. The molding compound 14 may form a hermetic or substantially hermetic seal between the glass lid 16 and the wall 10 in various implementations. In various implementations, the molding compound may include granular resins, granular epoxies, epoxies, thermoset resins, gel elastomers, encapsulants, potting compounds, composites, optical grade materials, silicone, and any combination thereof.

In some implementations, the glass lid may be etched, grooved, or flanged to increase the strength of the bond between the wall and the lid and also between the molding compound and the lid. By non-limiting example, the lid may be etched through laser grooving, a blade saw, or similar techniques. The etching of the glass may cause a cross section of the edge of the glass to resemble, by non-limiting example, a foot, a flange, a miter, a bevel, a double bevel, a bull nose, an ogee edge, or any shape extending from or receding into the glass. While the shape of the edge of the glass may be the same on all sides of the glass, in various implementations, different shapes of the edges may be present on one or more sides of the glass from the other sides of the glass. Shaping of the edge of the glass lid may also be used to enhance bonding when the lid is made of a material other than glass.

The hermetic seal formed through the bonding techniques and structures disclosed herein may protect the semiconductor package from moisture intrusion that is often caused by highly-accelerated temperature and humidity stress test (HAST) used to simulate operation of the device over time in a humid environment. In typical plastic leadless chip carriers (PLCC) and ceramic leadless chip carriers (CLCC), HAST and temperature humidity (TH) tests cause reliability issues because moisture eventually permeates the resin bonding interface between the glass and the dam thereby introducing moisture into the air cavity of the semiconductor package. The moisture intrusion induces other package reliability issues such as current leakage and image defect up to catastrophic failures like popcorning as the glass lid is cracked off the wall under the expansion of the moisture. In the present implementation of a semiconductor package 2, the molding compound over a surface of the glass lid and the upper portion of the wall may act as a barrier to moisture intrusion.

In addition to image sensors, the semiconductor package illustrated in FIG. 1 may also be utilized for back-illuminated sensors. The methods and principles disclosed herein may also be useful in forming die stacked devices with a narrow space between the die edge and pixel array of the device. Examples of die stacked devices may include, by non-limiting example, stacked image sensor and image sensor processor(s); stacked image sensor, image sensor processor(s), and memory; stacked image sensor, passive component die(s), and image sensor processor(s), and any combination thereof.

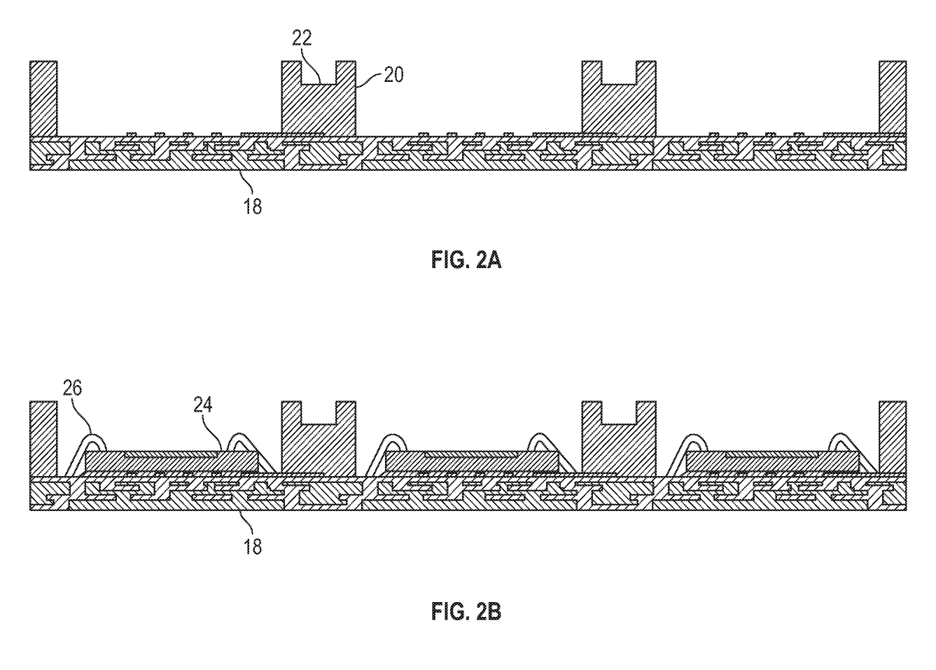

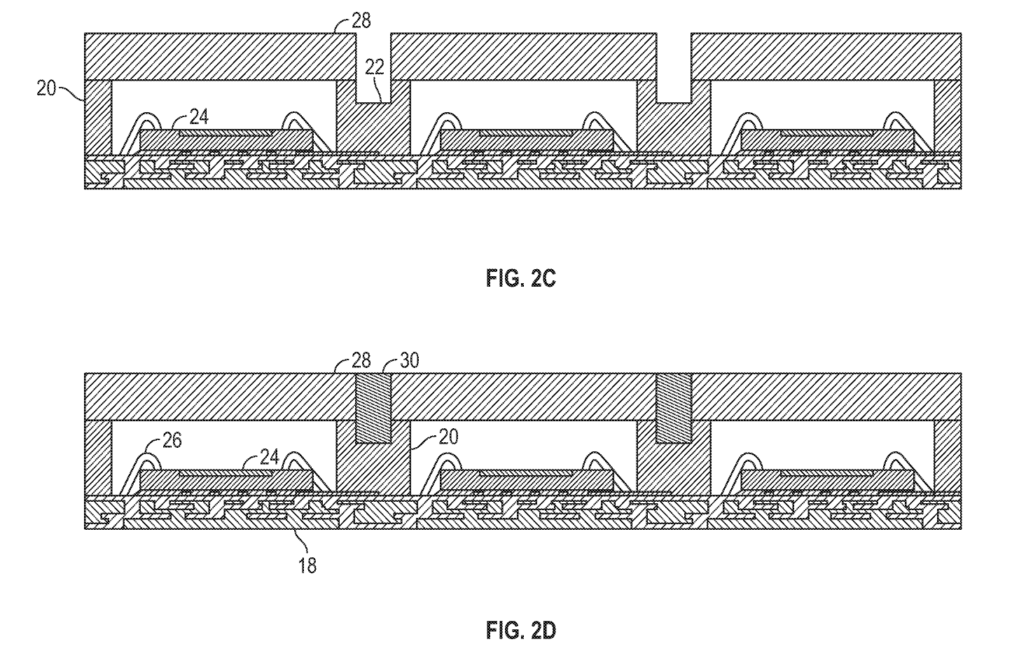

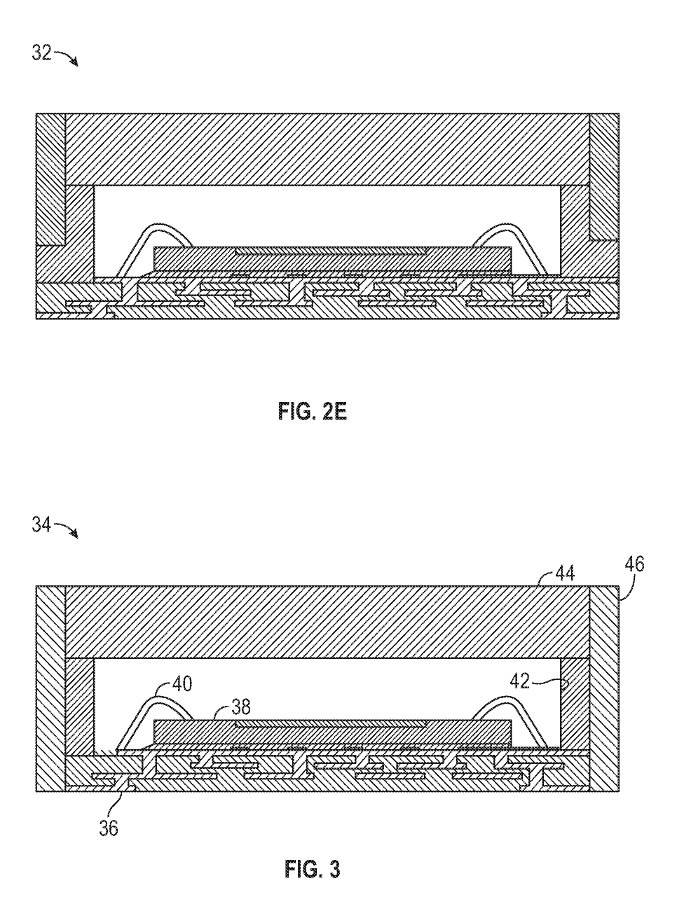

Referring to FIGS. 2A-2E, an implementation of a method of forming a semiconductor package is illustrated. In FIG. 2A, a substrate sheet 18 is illustrated. Two or more walls 20 are coupled to the substrate sheet 18. The walls 20 may be coupled to the substrate sheet 18 through epoxy or through the adhesion properties of the materials. In other implementations, the walls may be formed directly onto the substrate sheet 18 using a molding process. As illustrated in FIG. 2A, the walls 20 include molding dams 22 giving the upper surface of the walls a concave/grooved structure. The concave/grooved structure of the molding dams may be created using a molding tool. The walls/molding dams may be made directly from epoxy compound and may be formed through transfer molding, compression molding, injection molding, or other suitable methods. In various implementations, the walls may be formed of any other moldable material disclosed herein.

In other implementations, the concave/grooved structure of the molding dams may be formed using a process other than molding. By non-limiting example, the concave/grooved structure may be formed using cutting, etching, ablating, melting, or another process capable of shaping the material used to form the dam. Where these other processes are used, the material of the dam may not be a polymeric material, but could be, by non-limiting example, a composite, metal, semiconductor, or other rigid material capable of bonding with the glass lid.

Referring to FIG. 2B, three die 24 are mechanically and electrically coupled to the substrate 18 through two wire bonds per die 26. In other implementations, two or more wire bonds may be used on each die. In various implementations, the die may be coupled to the substrate through any of the other interconnect techniques such as those described previously. By non-limiting example, two or more die may be coupled to the substrate between each set of walls. The die 24 may include image sensor arrays in various implementations. In other implementations, back illuminated sensors may be used in the packaging. In still other implementations, as previously mentioned, this method may be used for three dimensional stacked die technologies.

Referring to FIG. 2C, three glass lids 28 are coupled to the walls 20. In various implementations, two or more glass lids may be coupled over two or more die 24. As can be seen in the FIG. 2C, the glass lids 28 do not cover the molding dams/concave surfaces/grooves 22 located in the top surfaces of the two or more walls. The glass lids couple to the wall at the edge of the trench in the walls. The glass lids may be adhered to the molding compound through the adhesion properties of the materials, or an adhesive or other bonding material may be employed. In various implementations, the lids may be formed of other transparent, translucent, or other optically transmissive material known in the art which allow light to pass through the lid. The edges of the lids may be shaped to improve adhesion to the molding compound such as forming a beveled edge or any of the other shapes as disclosed herein. Grooves may also be added to the lids through laser cutting or using a blade saw. The grooves may form a foot like shape on the lid to aid in better adhesion between the materials as described herein.

Referring to FIG. 2D, molding compound 30 is applied into the molding dam 22 of the two or more walls 20. The molding compound 30 extends across a thickness of the glass 28 and may securely couple the two or more glass lids 28 to the two or more walls 20. The molding compound 30 may form a hermetic or substantially hermetic seal between the glass lid 28 and the walls 20. In various implementations, the molding compound may include, by non-limiting example, granular resin, granular epoxy, resin, epoxy, silicone, acrylic, polyimide, any combination thereof, or any other polymeric or flowable material. The molding compound may be applied through, by non-limiting example, a dispenser, a coater, a molding process, or another other suitable method of dispensing a liquid material into the dam. After molding, the two or more semiconductor packages are then singulated at the molding dam/trench 22 between the packages. The packages may be singulated by various methods known in the art including sawing, water jet cutting, laser cutting and the like.

Referring to FIG. 2E, a singulated semiconductor package 32 is illustrated. The two or more semiconductor packages formed through this method may include, by non-limiting example, PLCCs, CLCCs, complementary-metal-oxide semiconductor (CMOS) image sensors (CIS), back illuminated sensor packages, three-dimensional stacked packages or other package types that include a cover over an internal cavity.

Referring to FIG. 3, another implementation of a semiconductor package is illustrated 34. The implementation of a semiconductor package 34 includes a substrate 36 having a die 38 electrically coupled thereto. In various implementations, the substrate may be, by non-limiting example, a printed circuit board, a ceramic material, a lead frame, or other suitable material known in the art. The printed circuit board could be made of Bismaleimide-Triazine (BT) resin, FR-4 grade glass-reinforced epoxy laminate, FR-5 grade glass-reinforced epoxy laminate, and any other material disclosed herein. More than one die may be coupled to the substrate in various implementations. In various implementations, the one or more die may be coupled in a stacked configuration

As illustrated in FIG. 3, the die 38 is mechanically and electrically coupled to the substrate 36 through two or more wire bonds 40. In various implementations, the die may be coupled to the substrate without wire bonds such as through, by non-limiting example, ball grid array (BGA) or land grid array (LGA) interconnects. As illustrated, a wall 42 is coupled to the substrate and to a glass lid 44. The wall 42 extends around a perimeter of the substrate 36/die 38 in various implementations.

As illustrated in FIG. 3, a metal layer 46 is coupled across a thickness of the substrate 36, the wall 42, and a thickness of the glass lid 44. In other implementations, the lid may include another transparent or clear material other than glass which may be any disclosed herein. The transparent material in various implementations may be polycarbonate, plastic, or other suitable materials known in the art. In some implementations, the metal layer 46 may include nickel, copper, aluminum, chromium, nickel, titanium, any combination thereof, or any other suitable metal that is stable and low cost. By non-limiting example, the metal layer 46 may form a hermetic seal for the one or more die. The metal layer may protect the semiconductor package 34 from electromagnetic interference (EMI) and electrostatic discharge (ESD).

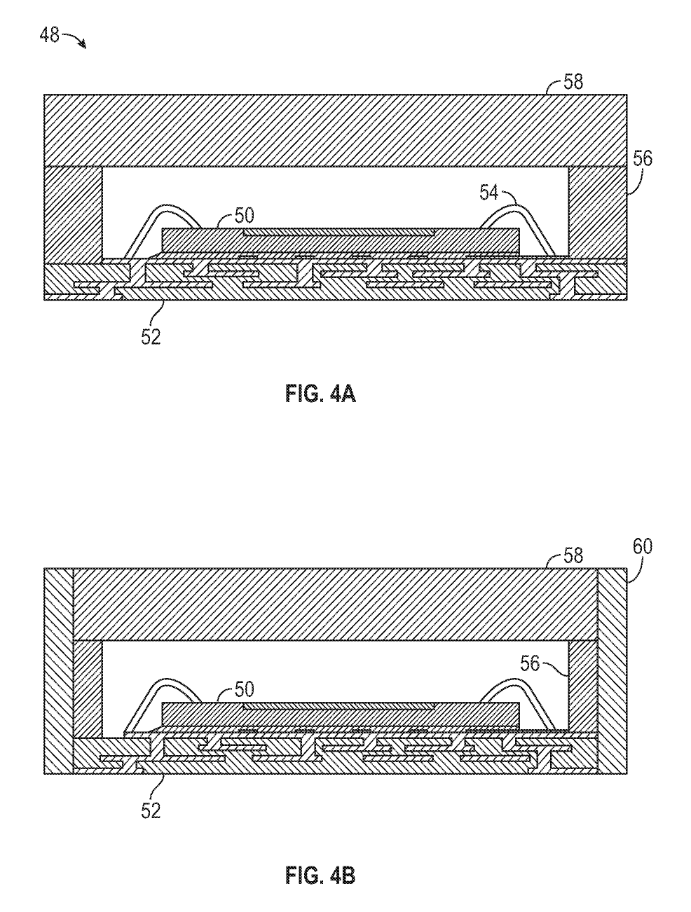

Referring to FIG. 4A-4B, an implementation of a method for forming a semiconductor package is illustrated. Referring to FIG. 4A, a semiconductor package 48 is provided. As illustrated, the semiconductor package 48 includes one die coupled to a substrate. In other implementations, more than one die may be coupled to the substrates. In other implementations, the semiconductor package 48 may include one or more die 50 coupled to a substrate 52. By non-limiting example, the substrate may include a printed circuit board made of any of the materials described herein. In other implementations, the substrate may include a ceramic or similar material.

As illustrated in FIG. 4A, the die is electrically and mechanically coupled to the substrate through two wire bonds 54. In some implementations, the one or more die may be in a stacked configuration in the package. In various implementations, one or more die may be electrically and mechanically coupled to the substrates through methods not involving wire bonds such as, by non-limiting example, a ball grid array, a land grid array or any other interconnect type disclosed herein.

As illustrated in FIG. 4A, a wall 56 is extending around a perimeter of the one die 50. The wall may be coupled to the substrate 52 and a glass lid 58. As previously described, the lid 58 may be made of another suitable optically transparent material, which may be any disclosed herein. The wall may be coupled to the substrate through epoxy or other similar materials as previously described or formed on the substrate as previously described. The glass lid 58 may be coupled to the wall 56 through resin, other suitable materials, or through the adhesion properties of the structures.

Referring to FIG. 4B, a metal layer 60 is coupled to the wall of semiconductor package 48. C-mode scanning acoustic microscopy (CSAM) may be performed to test for delamination between the glass lid and wall of the package prior to the addition of the metal layer. The bonding force of the glass to the wall may be tested using glass shear methods prior to application of the metal layer. In various implementations, the metal layer 60 may be coupled across a thickness of the substrate 52, the wall 56, and a thickness of the glass lid 58 forming a hermetic seal. The metal layer 60 may be applied through, by non-limiting example, plasma sputtering, chemical vapor deposition (CVD), electrical plating, electroless plating, immersion plating, or any method of depositing metal onto a substantially flat surface. In various implementations, a chemical vapor deposition machine may be used to make a seed metal on the sides of the package before adding metal plating to increase the thickness of the metal layer. The metal may include, by non-limiting example, one of nickel, copper, aluminum, chromium, titanium, any combination thereof, or another stable metal. The use of the metal layer may similarly bond the glass to the wall and may in various implementations, form a hermetic or substantially hermetic seal for the package. The metal layer may also act to protect the semiconductor package from electromagnetic interference (EMI) and electrostatic discharge (ESD).

In places where the description above refers to particular implementations of semiconductor packages and implementing components, sub-components, methods and sub-methods, it should be readily apparent that a number of modifications may be made without departing from the spirit thereof and that these implementations, implementing components, sub-components, methods and sub-methods may be applied to other semiconductor packages.

1. A semiconductor package comprising:
a substrate;
a die electrically coupled to the substrate;
a wall coupled to the substrate the wall extending around a perimeter of the die, the wall comprising a molding dam formed therein;
a glass lid coupled to the wall and the molding dam; and
a mold compound coupled into the molding dam and across a thickness of the glass lid.

2. The semiconductor package of claim 1, wherein the substrate is one of a printed circuit board, a ceramic material, and a lead frame.

3. The semiconductor package of claim 1, wherein the wall is formed through one of transfer molding, compression molding, and injection molding.

4. The semiconductor package of claim 1, wherein the molding compound is one of resin, epoxy, silicon, acrylic, polyimide, and any combination thereof.

5. The semiconductor package of claim 1, wherein the molding compound forms a substantially hermetic seal.

6. The semiconductor package of claim 1, wherein the semiconductor package is one of a plastic leadless chip carrier (PLCC), a ceramic leadless chip carrier (CLCC), and a complementary metal-oxide-semiconductor (CMOS) image sensor (CIS).

7. A semiconductor package comprising:
a substrate;
one or more die electrically coupled to the substrate;
a wall coupled to the substrate and a glass lid, the wall extending around a perimeter of the one or more die;
a metal layer coupled across a thickness of the substrate, the wall, and a thickness of the glass lid;
wherein the metal layer forms a substantially hermetic seal for the one or more die.

8. The semiconductor package of claim 7, wherein the substrate is one of a printed circuit board, a ceramic material, and a lead frame.

9. The semiconductor package of claim 7, wherein the metal layer comprises one of nickel, copper, aluminum, chromium, and any combination thereof.

10. The semiconductor package of claim 7, wherein the metal layer is coupled to semiconductor package through one of plasma sputtering, chemical vapor deposition, electrical plating, electroless plating, and immersion plating.

11. The semiconductor package of claim 7, wherein the metal layer protects the semiconductor package from electromagnetic inference (EMI) and electrostatic discharge (ESD).

12. The semiconductor package of claim 7, wherein the semiconductor package is one of a plastic leadless chip carrier (PLCC), a ceramic leadless chip carrier (CLCC), and a complementary metal-oxide-semiconductor (CMOS) image sensor (CIS).

13. A method for forming a semiconductor package, the method comprising:
providing a substrate sheet;
coupling two or more walls to the substrate sheet, the two or more walls located around two or more die locations of the substrate sheet, the two or more walls comprising a molding dam therein;
coupling two or more die to the substrate at the two or more die locations;
coupling two or more glass lids to the two or more walls over the two or more die;
applying mold compound into the molding dam of the two or more walls; and
singulating two or more semiconductor packages at the molding dam;
wherein the molding dam securely couples the two or more glass lids to the two or more walls.

14. The method of claim 12, wherein the molding compound extends across a thickness of the glass.

15. The method of claim 12, wherein the substrate sheet comprises one of a printed circuit board, a ceramic material, and a lead frame.

16. The method of claim 12, wherein the two or more walls are formed through one of transfer molding, compression molding, and injection molding.

17. The method of claim 12, wherein the mold compound is one of resin, epoxy, silicon, acrylic, polyimide, and any combination thereof.

18. The method of claim 12, wherein the molding compound forms a substantially hermetic seal.

19. The method of claim 13, wherein the mold compound is applied through one of a dispenser and a coater.

20. The method of claim 12, wherein the two or more semiconductor packages comprise one of plastic leadless chip carriers (PLCC), a ceramic leadless chip carriers (CLCC), and complementary metal-oxide-semiconductor (CMOS) image sensors (CIS).

21. The semiconductor package of claim 1, wherein the die is electrically coupled to the substrate through wire bonds.

22. The semiconductor package of claim 1, wherein the die is electrically coupled to the substrate through one of ball grid array (BGA) interconnects and land grid array (LGA) interconnects.

23. The semiconductor package of claim 7, wherein the one or more die are electrically coupled to the substrate die through wire bonds.

24. The semiconductor package of claim 7, wherein the one or more die are electrically coupled to the substrate through one of ball grid array (BGA) interconnects and land grid array (LGA) interconnects.
